(19) United States
(12) Patent Application Publication
(10) Pub. No.: US 2026/0300660 A1
(43) Pub. Date: Oct. 1, 2026

(54) COMPONENT MANAGEMENT DEVICE AND COMPONENT MANAGEMENT METHOD

(71) Applicant: FUJI CORPORATION, Chiryu (JP)

(72) Inventors: Kohei SUGIHARA, Nishio-shi (JP); Teruyuki OHASHI, Anjo-shi (JP)

(73) Assignee: FUJI CORPORATION, Chiryu (JP)

(21) Appl. No.: 19/474,829

(22) PCT Filed: May 23, 2023
(86) PCT No.: PCT/JP2023/019146

§ 371 Date: Oct. 13, 2025

(51) Int. Cl. G06K 7/14; G06K 7/10

(52) U.S. Cl. CPC G06K 7/1417; G06K 7/10366; G06K 7/1413

(57) ABSTRACT

A component management device includes an acquisition section and a storage section. The acquisition section is configured to acquire, from an identification member having component identification information for identifying components to be mounted on a board, the component identification information for at least one of a first component that is some of the multiple components that are supplied from a component supply device configured to supply the components after the component supply device is mounted on a component mounter, a second component that is some of the multiple components that are supplied from the same component supply device to the boards of the same type, and a third component that is the component selected each time a predetermined number of the components are supplied from the same component supply device and that is some of the predetermined number of the components. The storage section is configured to store, in a storage device, the component identification information of the components that is acquired by the acquisition section and board identification information for identifying the board on which the components are mounted, in association with each other.

### TECHNICAL FIELD

The present description discloses a technique related to a component management device and a component management method.

### BACKGROUND ART

A component management device described in Patent Literature 1 includes an acquisition section and a storage section, When components are sequentially supplied from a carrier tape including multiple cavities accommodating the components to be mounted on a board, the acquisition section acquires position information of the cavity accommodating the components. The storage section stores position information of the cavity acquired by the acquisition section and identification information for identifying a reel around which the carrier tape is wound in the storage device in association with each other.

### CITATION LIST

### Patent Literature

Patent Literature 1: WO 2021/106119

### BRIEF SUMMARY

### Technical Problem

For example, by using component identification information for identifying a component, it is possible to track and investigate the component supplied from a component supply device. However, when the component management device acquires the component identification information for all the components supplied from the component supply device, it takes time to acquire the component identification information, and production efficiency may decrease.

In view of such circumstances, the present description discloses a component management device and a component management method capable of acquiring component identification information for a predetermined component supplied from a component supply device and storing the component identification information in a storage device.

### Solution to Problem

The present description discloses a component management device including an acquisition section and a storage section. The acquisition section is configured to acquire, from an identification member having component identification information for identifying components to be mounted on a board, the component identification information for at least one of a first component that is some of the multiple components that are supplied from a component supply device configured to supply the components after the component supply device is mounted on the component mounter, a second component that is some of the multiple components that are supplied from the same component supply device to the boards of the same type, and a third component that is the component selected each time a predetermined number of the components are supplied from the same component supply device and that is some of the predetermined number of the components. The storage section is configured to store, in a storage device, the component identification information of the components that is acquired by the acquisition section and board identification information for identifying the board on which the components are mounted in association with each other.

The present description discloses a component management method including an acquisition step and a storage step. In the acquisition step, the component identification information is acquired from an identification member having component identification information for identifying components to be mounted on a board for at least one of a first component that is some of the multiple components that are supplied from a component supply device configured to supply the components after the component supply device is mounted on the component mounter, a second component that is some of the multiple components that are supplied from the same component supply device to the boards of the same type, and a third component that is the component selected each time a predetermined number of the components are supplied from the same component supply device and that is some of the predetermined number of the components. In the storage step, the component identification information of the components that is acquired by the acquisition step and board identification information for identifying the board on which the components are mounted are stored in a storage device in association with each other.

### Advantageous Effects

With the above component management device, it is possible to acquire the component identification information of the predetermined component supplied from the component supply device and store the component identification information in the storage device. The above description of the component management device can be similarly applied to the component management method.

### BRIEF DESCRIPTION OF DRAWINGS

FIG. 1 is a plan view illustrating a configuration example of a component mounter.

FIG. 2 is a block diagram illustrating an example of a control block of a component management device.

FIG. 3 is a flowchart illustrating an example of a procedure of control performed by the component management device.

FIG. 4 is a plan view illustrating an example of a carrier tape.

FIG. 5 is a cross-sectional view of the carrier tape of FIG. 4.

FIG. 6 is a diagram illustrating an example of a first component in the carrier tape.

FIG. 7 is a diagram illustrating an example of a second component in the carrier tape.

FIG. 8 is a diagram illustrating an example of a third component in the carrier tape.

FIG. 9 is a diagram illustrating an example of a collection order in a case where components are collected from a tray.

FIG. 10 is a diagram illustrating another example of the collection order in a case where the components are collected from the tray.

### DESCRIPTION OF EMBODIMENTS

### 1. Embodiment

### 1-1. Configuration Example of Component Mounter 10

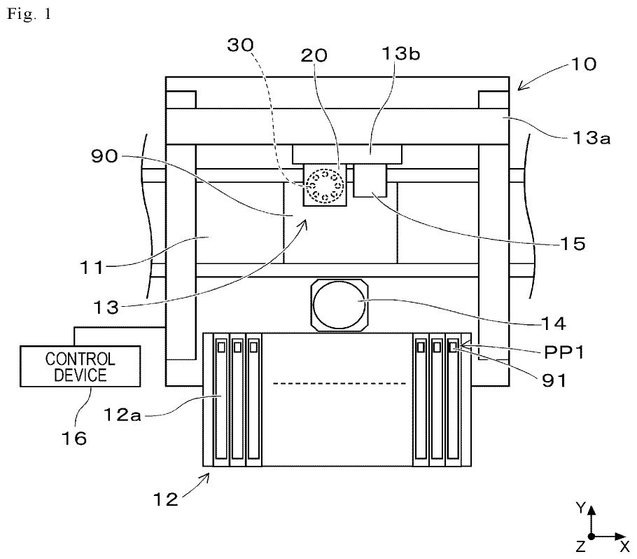

Component mounter 10 mounts component 91 on board 90. As illustrated in FIG. 1, component mounter 10 includes board conveyance device 11, component supply device 12, component transfer device 13, component camera 14, board camera 15, and control device 16.

For example, board conveyance device II includes a belt conveyor and the like, and conveys board 90 in a conveyance direction (X-axis direction). Board 90 is a circuit board, on which an electronic circuit, an electrical circuit, a magnetic circuit, or the like are formed. Board conveyance device 11 conveys board 90 into component mounter 10 and positions board 90 at a predetermined position in component mounter 10. After a process of mounting multiple components 91 using component mounter 10 is ended, board conveyance device 11 conveys board 90 out of component mounter 10.

Component supply device 12 supplies component 91 to be mounted on board 90. Component supply device 12 includes multiple feeders 12a, which are provided along the conveyance direction (X-axis direction) of board 90. Each of multiple feeders 12a is equipped with a reel. Carrier tape 80 in which components 91 are accommodated is wound around the reel. Feeder 12a pitch-feeds carrier tape 80 to supply components 91 so that component 91 can be collected at collection position PP1 located on a distal end side of feeder 12a. In addition, component supply device 12 can also supply an electronic component (for example, a leaded component or the like) which is relatively large as compared with a chip component or the like in a state of being disposed on tray 12b.

Component transfer device 13 includes head drive device 13a and moving table 13b. Head drive device 13a is configured to move moving table 13b in the X-axis direction and a Y-axis direction (a direction orthogonal to the X-axis direction on a horizontal plane) by means of a linear motion mechanism. Mounting head 20 is detachably (exchangeably) provided on moving table 13b by a clamp member. Mounting head 20 collects and holds component 91 supplied from component supply device 12 by using at least one holding member 30, and mounts component 91 on board 90 positioned by board conveyance device 11. For example, a suction nozzle, a chuck, or the like can be used as holding member 30.

As component camera 14 and board camera 15, a well-known imaging device can be used. Component camera 14 is fixed to a base of component mounter 10 such that an optical axis is oriented upward in a vertical direction (in a Z-axis direction orthogonal to the X-axis direction and the Y-axis direction). Component camera 14 can image component 91 held by holding member 30 from below. Board camera 15 is provided on moving table 13b of component transfer device 13 such that an optical axis thereof is oriented downwards in the vertical direction (Z-axis direction). Board camera 15 can image board 90 from above.

Board camera 15 can also image component 91 from above at collection position PP1 of component 91. Component camera 14 and board camera 15 perform imaging based on a control signal transmitted from control device 16, Image data of images captured by component camera 14 and board camera 15 is transmitted to control device 16.

Control device 16 includes a computing device and a storage device which are well-known, and is provided with a control circuit. Information, image data, and the like output from various sensors provided in component mounter 10 are input to control device 16. Control device 16 transmits control signals to each device based on a control program, a predetermined mounting condition set in advance, and the like.

For example, control device 16 causes board camera 15 to image board 90 positioned by board conveyance device 11. Control device 16 performs image processing on the image captured by board camera 15 to recognize a positioning state of board 90. Moreover, control device 16 causes holding member 30 to collect and hold component 91 supplied by component supply device 12, and causes component camera 14 to image component 91 held by holding member 30. Control device 16 performs the image processing on the image captured by component camera 14 to recognize a holding posture of component 91.

Control device 16 moves holding member 30 toward a position above a planned mounting position that is set in advance by the control program or the like. Further, based on the positioning state of board 90, the holding posture of component 91, and the like, control device 16 corrects the planned mounting position to set the mounting position on which component 91 is actually mounted. The planned mounting position and the mounting position include a rotation angle in addition to the position (an X-axis coordinate and a Y-axis coordinate).

Control device 16 corrects a target position (the X-axis coordinate and the Y-axis coordinate) and the rotation angle of holding member 30 according to the mounting position. Control device 16 lowers holding member 30 at the corrected rotation angle at the corrected target position to mount component 91 on board 90. Control device 16 repeats the pick-and-place cycle described above to execute the mounting process of mounting multiple components 91 on board 90. A total time of a time required for a predetermined number of cycles of the pick-and-place cycle for component 91 and a time required for the loading and unloading of board 90 corresponds to a cycle time per board 90.

### 1-2. Configuration Examples of Component Management Device 40

For example, by using component identification information for identifying component 91. it is possible to track and investigate component 91 supplied from component supply device 12. However, when component management device 40 acquires the component identification information for all components 91 supplied from component supply device 12, it takes time to acquire the component identification information, and production efficiency may decrease.

Therefore, component management device 40 includes acquisition section 41 and storage section 42. Component management device 40 may include complementing section 43.

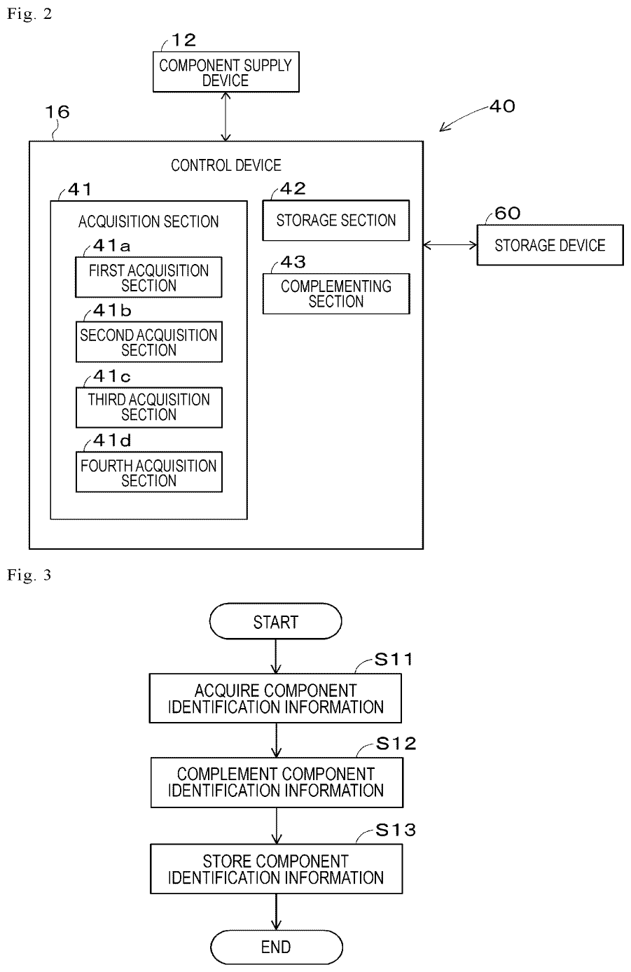

As illustrated in FIG. 2, component management device 40 of the embodiment includes acquisition section 41, storage section 42, and complementing section 43. At least one of acquisition section 41, storage section 42, and complementing section 43 can be provided in various control devices and management devices. At least one of acquisition section 41, storage section 42, and complementing section 43 may be provided on a cloud. As illustrated in FIG. 2, in the embodiment, acquisition section 41, storage section 42, and complementing section 43 are provided in control device 16 of component mounter 10.

In addition, component management device 40 executes control according to a flowchart illustrated in FIG. 3. Acquisition section 41 performs processing illustrated in step S11. Storage section 42 performs processing illustrated in step S13. Complementing section 43 performs processing illustrated in step S12. The matters described in the present description can be appropriately selected and applied. Further, the matters described in the present description can be appropriately combined.

### 1-2-1. Acquisition Section 41

Acquisition section 41 acquires the component identification information from identification member 70 having the component identification information for identifying component 91 for at least one of first component 91a, second component 91b, and third component 91c (step S11 illustrated in FIG. 3). Acquisition section 41 may take various forms as long as the component identification information can be acquired from identification member 70 for component 91.

Identification member 70 has various types of information on component 91. For example, identification member 70 can have information on at least one of the component identification information, a type, a vendor, and a lot of component 91. Acquisition section 41 can identify component 91 supplied from component supply device 12 by acquiring the component identification information of component 91 from identification member 70. Similarly, acquisition section 41 can acquire the above-described information on component 91 supplied from component supply device 12.

A known identification member can be used as identification member 70. For example, a one-dimensional code, a two-dimensional code, or a wireless tag can be used as identification member 70. When identification member 70 is a one-dimensional code or a two-dimensional code, acquisition section 41 can acquire various types of information such as the component identification information using a known code reader (a barcode reader capable of reading a barcode, an imaging device capable of reading a two-dimensional code, or the like). In a case where identification member 70 is a wireless tag, acquisition section 41 can acquire various types of information such as the component identification information using a known wireless device capable of wireless communication with the wireless tag.

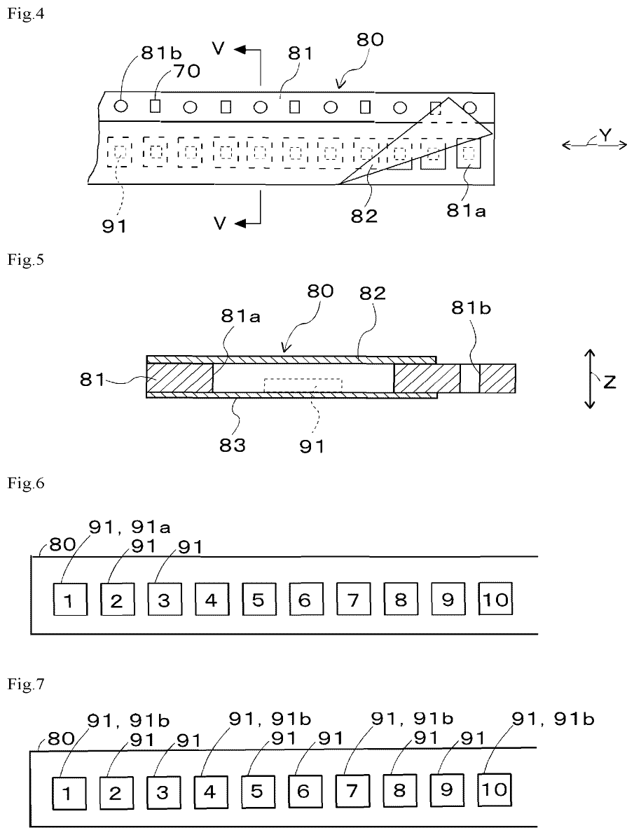

As described above, component supply device 12 can include feeder 12a. Feeder 12a pitch-feeds carrier tape 80 in which components 91 are accommodated, and supplies component 91 so that component 91 can be collected at collection position PP1. As illustrated in FIGS. 4 and 5, for example, carrier tape 80 according to the embodiment includes base tape 81, cover tape 82, and bottom tape 83. Base tape 81 is a base portion of carrier tape 80, and is provided with multiple cavities 81a and multiple feed holes 81b.

Component 91 is accommodated in each of multiple cavities 81a. Multiple cavities 81a are provided at predetermined pitch intervals in a longitudinal direction of carrier tape 80 at a center portion of base tape 81 in a width direction. Multiple feed holes 81b are used when carrier tape 80 is conveyed in the conveyance direction (Y-axis direction in component mounter 10 illustrated in FIG. 1). Multiple feed holes 81b are provided at predetermined pitch intervals in the longitudinal direction of carrier tape 80 on a one end side of base tape 81 in the width direction.

Cover tape 82 closes cavity 81a of base tape 81. Cover tape 82 is attached to upper surfaces of both end portions of base tape 81 in the width direction with, for example, an adhesive. Bottom tape 83 is attached to a lower surface of base tape 81 with, for example, an adhesive, and prevents component 91 accommodated in cavity Sla from falling off. Carrier tape 80 may be an embossed tape, a paper tape, or the like in which base tape 81 and bottom tape 83 are integrally formed.

Identification member 70 can be provided at any position of base tape 81. For example, identification member 70 can be provided between feed holes 81b capable of the pitch-feed of carrier tape 80 or between cavities 81a in which components 91 are accommodated. In carrier tape 80 illustrated in FIG. 4, identification member 70 is provided between feed holes 81b. In this case, acquisition section 41 can acquire the component identification information from identification member 70 from which the component identification information can be acquired along with the pitch-feed of carrier tape 80.

Specifically, in carrier tape 80 illustrated in FIG. 4, cavities 81a facing feed holes 81b in the width direction and cavities 81a facing identification member 70 in the width direction are alternately provided in the longitudinal direction. Therefore, as carrier tape 80 is pitch-fed, the two types of cavities 81a are alternately positioned at collection position PPL When cavity 81a facing identification member 70 is positioned at collection position PP1; acquisition section 41 can acquire the component identification information from identification member 70. When cavity 81a facing feed hole 81b is positioned at collection position PP1, acquisition section 41 cannot acquire the component identification information. In this way, acquisition section 41 can acquire the component identification information from identification member 70 from which the component identification information can be acquired along with the pitch-feed of carrier tape 80.

When identification member 70 is provided between cavities 81a, acquisition section 41 can acquire the component identification information from identification member 70 each time cavity 81a is positioned at collection position PP1 along with the pitch-feed of carrier tape 80. In any of the above-described embodiments, acquisition section 41 can acquire various types of information such as the component identification information using the above-described reading device. For example, identification member 70 illustrated in FIG. 4 is a two-dimensional code. For example, acquisition section 41 can acquire various types of information such as the component identification information by reading the two-dimensional code using board camera 15.

However, as the number of times by which acquisition section 41 acquires the component identification information increases, it takes more time to acquire the component identification information, and the production efficiency may decrease. Therefore, acquisition section 41 acquires the component identification information for predetermined component 91 supplied from component supply device 12. Specifically, acquisition section 41 acquires the component identification information from identification member 70 for at least one of first component 91a, second component 91b, and third component 91c. In the present description, for convenience of description, at least one of first component 91a, second component 91b, and third component 91c is referred to as predetermined component 91.

First component 91a refers to some of multiple components 91 supplied from component supply device 12 after component supply device 12 is mounted on component mounter 10. FIG. 6 is a plan view schematically illustrating components 91 accommodated in carrier tape 80. The number assigned to component 91 indicates an accommodation order in which component 91 is stored in carrier tape 80, and component 91 is collected in the accommodation order. The same applies to FIG. 7 and & as described above with reference to FIG. 6.

For example, component 91 initially supplied from component supply device 12 after component supply device 12 is mounted on component mounter 10 is component 90 numbered 1. Component 91 supplied from component supply device 12 subsequent to component 90 numbered 1 is component 90 numbered 2. Similarly, components 91 are supplied from component supply device 12 in an order of component 90 numbered 3, component 91 numbered 4, and component 90 numbered 5 (hereinafter, abbreviated). First component 91a may be some of multiple components 91 supplied from component supply device 12 after component supply device 12 is mounted on component mounter 10, and can be freely designated.

First component 91a may be one component 91 among multiple components 91 described above, or may be multiple components 91. As illustrated in FIG. 6, for example, first component 91a can be component 91 (in FIG. 6, component 90 numbered 1) initially supplied from component supply device 12 after component supply device 12 is mounted on component mounter 10. Accordingly, acquisition section 41 can minimize the time required to acquire the component identification information for first component 91a.

Second component 91b refers to some of multiple components 91 supplied from same component supply device 12 to each of boards 90 of the same type. As illustrated in FIG. 7, for example, it is assumed that a predetermined number (three in FIG. 7) of components 91 are supplied from same component supply device 12 to boards 90 of the same type.

Specifically, components 91 numbered 1 to 3 are supplied to first board 90 among boards 90 of the same type. Components 91 numbered 4 to 6 are supplied to second board 90 among boards 90 of the same type.

Thereafter, the same applies, and components 91 numbered 7 to 9 are supplied to third board 90 among boards 90 of the same type. For example, component mounter 10 can mount a predetermined number (three) of components 91 on each of boards 90 of the same type by executing the pick-and-place cycle described above for the same number of cycles (three cycles in this case) as the predetermined number. Second component 91b may be some of multiple components 91 supplied from same component supply device 12 to boards 90 of the same type, and can be freely designated.

In addition, second component 91b may be one component 91 among: multiple components 91, or may be multiple components 91, As illustrated in FIG. 7, for example, second component 91b may be component 91 initially supplied from same component supply device 12 to each of boards 90 of the same type (in FIG. 7, components 91 numbered 1, 4, 7, and 10). Accordingly, acquisition section 41 can minimize the time required to acquire the component identification information for second component 91b.

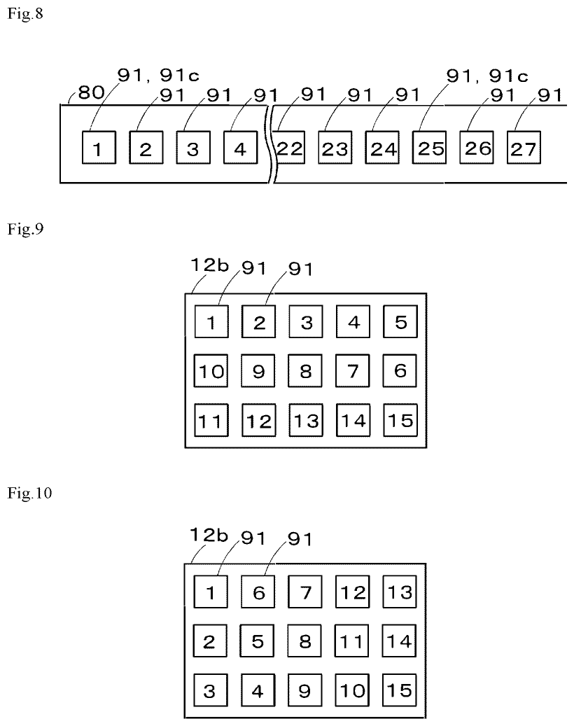

Third component 91c is component 91 selected each time a predetermined number of components 91 are supplied from same component supply device 12, and is some of the predetermined number of components 91. As illustrated in FIG. 8, for example, it is assumed that the predetermined number (24 in FIG. 8) of components 91 are repeatedly supplied from same component supply device 12. Specifically, after components 91 numbered 1 to 24 are supplied, components 91 numbered 25 to 48 are supplied. Thereafter, the same applies, and the supply of predetermined number (24) of components 91 is repeated.

As described above, component mounter 10 includes mounting head 20 including holding member 30 that collects and holds component 91 to mount component 91 on board 90. Mounting head 20 may include at least one holding member 30, or may include multiple holding members 30. In this case, the predetermined number can be the same as the number of holding members 30 provided in mounting head 20. In the example illustrated in FIG. 8, mounting head 20 includes multiple (24) holding members 30, and the predetermined number (24) of components 91 are repeatedly supplied. As described above, acquisition section 41 can also acquire the component identification information for some of the predetermined number (24) of components 91 supplied using mounting head 20.

Third component 91c may be some of the predetermined number of components 91, and can be freely designated. In addition, third component 91c may be one component 91 among the predetermined number of components 91, or may be multiple components 91. As illustrated in FIG. 8, for example, third component 91c may be first-in-order component 91 (components 91 numbered 1 and 25 in FIG. 8) among the predetermined number of components 91. Accordingly, acquisition section 41 can minimize the time required to acquire the component identification information for third component 91c.

Acquisition section 41 can also change predetermined component 91 (at least one of first component 91a, second component 91b, and third component 91c) for which the component identification information is acquired for each type of component 91. Acquisition section 41 can also change predetermined component 91 for which the component identification information is acquired for each type of board 90, Further, acquisition section 41 can also change predetermined component 91 for which the component identification information is acquired for each device (for example, component mounter 10, a production line, or the like).

In carrier tape 80 illustrated in FIG. 4, in a case where cavity 81a facing identification member 70 is positioned at collection position PP1, acquisition section 41 can acquire the component identification information from identification member 70. In a case where cavity 81a facing feed hole 81b is positioned at collection position PP1, acquisition section 41 cannot acquire the component identification information. As described above, depending on a form of identification member 70, there is a possibility that the component identification information cannot be acquired for predetermined component 91 for which the component identification information is desired to be acquired.

Therefore, when acquisition section 41 cannot acquire the component identification information, acquisition section 41 can attempt to acquire the component identification information for at least one of component 91 supplied subsequent to first component 91a, component 91 supplied subsequent to second component 91b, and another component 91 among the predetermined number of components 91. For example, it is assumed that acquisition section 41 attempts to acquire the component identification information of first component 91a, and first component 91a is component 91 (component 90 numbered 1 illustrated in FIG. 6) initially supplied from component supply device 12 after component supply device 12 is mounted on component mounter 10.

In a case where the component identification information on component 91 cannot be acquired, acquisition section 41 can attempt to acquire the component identification information on component 91 (component 90 numbered 2 illustrated in FIG. 6) supplied subsequent to first component 91a. The same applies to a case where acquisition section 41 cannot acquire the component identification information on second component 91b. The same applies to a case where acquisition section 41 cannot acquire the component identification information on third component 91c. Acquisition section 41 can repeat the above-described attempt until the component identification information is acquired. The above description of feeder 12a can be similarly applied to tray 12b on which components 91 are arranged.

Acquisition section 41 can acquire the component identification information in various situations. Specifically, acquisition section 41 can include at least one of first acquisition section 41a, second acquisition section 41b, third acquisition section 41c, and fourth acquisition section 41d. In a case where component 91 is collected from component supply device 12, first acquisition section 41 a acquires the component identification information from above identification member 70. First acquisition section 41a is in the form described above, and identification member 70 can be provided on, for example, a supply medium for supplying component 91.

As described above, when component supply device 12 is feeder 12a, identification member 70 can be provided on base tape 81 of carrier tape 80, In a case where component supply device 12 is tray 12b, identification member 70 can be provided in tray 12b, for example. Identification member 70 can also be provided on an upper surface of component 91. In a case where component 91 is collected from component supply device 12, first acquisition section 41a acquires the component identification information from above identification member 70. For example, first acquisition section 41a can acquire various types of information such as the component identification information by reading identification member 70 using board camera 15 or the like.

In a case where component 91 is held by holding member 30, second acquisition section 41b acquires the component identification information from below identification member 70 provided on a lower surface of component 91. In this embodiment, identification member 70 can be provided on the lower surface of component 91. For example, second acquisition section 41b can read identification member 70 using component camera 14 or the like and acquire various types of information such as the component identification information.

In a case where component 91 is mounted on board 90 by holding member 30, third acquisition section 41c acquires the component identification information from above identification member 70 provided on the upper surface of component 91. In this embodiment, identification member 70 can be provided on the upper surface of component 91. For example, third acquisition section 41c can acquire various types of information such as the component identification information by reading identification member 70 using board camera 15 or the like. For example, a one-dimensional code or a two-dimensional code can be used as identification member 70 in a case where first acquisition section 41a, second acquisition section 41b, or third acquisition section 41c acquires the component identification information.

In a case where identification member 70 is a wireless tag, fourth acquisition section 41d acquires the component identification information via wireless communication with the wireless tag. The wireless tag can be provided on base tape 81 of carrier tape 80, tray 12b, component 91, or the like. Fourth acquisition section 41d can acquire various types of information such as the component identification information using a known wireless device capable of wireless communication with the wireless tag.

Acquisition section 41 can also change at least one of first acquisition section 41a, second acquisition section 41b, third acquisition section 41c, and fourth acquisition section 41d for each type of component 91. Acquisition section 41 can also change at least one of first acquisition section 41a, second acquisition section 41b, third acquisition section 41c, and fourth acquisition section 41d for each type of board 90. Further, acquisition section 41 can also change at least one of first acquisition section 41a, second acquisition section 41b, third acquisition section 41c, and fourth acquisition section 41d for each device (for example, component mounter 10, the production line, or the like).

### 1-2-2. Storage Section 42 and Complementing Section 43

Storage section 42 stores the component identification information of component 91 acquired by acquisition section 41 and the board identification information for identifying board 90 on which component 91 is mounted in storage device 60 in association with each other (step S13 illustrated in FIG. 3). Storage device 60 need only store the component identification information and the board identification information in association with each other, and a known storage device (database) can be used. Storage device 60 can also be provided on a cloud. For example, storage device 60 according to the embodiment is provided in a storage device (database) of a management device that manages component mounter 10. Accordingly, a worker or a production management device can track and investigate component 91 supplied from component supply device 12.

Storage section 42 can also store the component identification information of component 91 acquired by acquisition section 41, the board identification information for identifying board 90 on which component 91 is mounted, and mounting position information for specifying a mounting position at which component 91 is mounted on board 90 in storage device 60 in association with each other. When component 91 supplied from component supply device 12 is discarded without being mounted on board 90, storage section 42 can store the component identification information of component 91 acquired by acquisition section 41 and discard information indicating that component 91 has been discarded in storage device 60 in association with each other.

Storage section 42 can also store, in storage device 60, component supply device information for specifying component supply device 12 that has supplied component 91, component mounter information for specifying component mounter 10 equipped with component supply device 12 that has supplied component 91, and the like. In addition, storage section 42 can also store date and time information for specifying a date and time when component 91 is supplied, worker information for specifying a worker who prepares component supply device 12, environmental information for specifying an ambient temperature and humidity of a production facility when component 91 is supplied, and the like in storage device 60.

Acquisition section 41 acquires the component identification information from identification member 70 for predetermined component 91 supplied from component supply device 12 (at least one of first component 91a, second component 91b, and third component 91c). Therefore, components 91 supplied from component supply device 12 include component 91 for which the component identification information is not acquired by acquisition section 41. Therefore, complementing section 43 complements the component identification information of component 91 for which the component identification information is not acquired by acquisition section 41, based on a relative order or a relative position with respect to component 91 for which the component identification information is acquired by acquisition section 41 (step S12 illustrated in FIG. 3).

For example, it is possible to use, as component supply device 12, feeder 12a that pitch-feeds carrier tape 80 in which components 91 are accommodated, and supplies component 91 so that component 91 can be collected at collection position PP1. In this case, as the component identification information, information indicating the accommodation order in which components 91 are accommodated in carrier tape 80 can be used. For example, it is assumed that acquisition section 41 acquires the component identification information for component 90 numbered 1 illustrated in FIG. 6, It is assumed that the component identification information of component 91 is represented by information AAA0001. Information AAA0001 includes symbol portion AAA and numeric portion 0001.

Numeric portion 0001 indicates the accommodation order in which component 90 numbered 1 is accommodated in carrier tape 80. For example, complementing section 43 can represent the component identification information of component 90 numbered 2 accommodated subsequent to component 90 numbered 1 by information AAA00011.

Information AAA00011 includes symbol portion AAA, numeric portion 0001, and relative order portion 1. Relative order portion 1 indicates a relative order (in this case, first) for component 91 for which the component identification information is acquired by acquisition section 41 (in this case, component 91 of which the component identification information is represented by information AAA0001).

The complementing section 43 represents the component identification information of component 90 numbered 3 accommodated subsequent to component 90 numbered 2 by information AAA00012. In this case, the component identification information includes relative order portion 2. Relative order portion 2 indicates a relative order (in this case, second) for component 91 for which the component identification information is acquired by acquisition section 41 (component 91 of which the component identification information is represented by information AAA0001). The same applies to components 91 numbered 4 and above, and the relative order indicates an accommodation order of components 91 in carrier tape 80 starting from component 91 for which the component identification information is acquired by acquisition section 41 in a case where component supply device 12 is feeder 12a. Symbol portion AAA indicates various types of information on component 91.

As illustrated in FIGS. 9 and 10, component supply device 12 may use tray 12b on which components 91 are arranged. In this case, as the component identification information, information indicating a collection order in a case where component 91 is collected from tray 12b by holding member 30 or information indicating a position of component 91 in tray 12b can be used. FIGS. 9 and 10 are plan views schematically showing components 91 arranged on tray 12b. The number attached to component 91 indicates an example of a collection order in a case where component 91 is collected.

Specifically, in tray 12b illustrated in FIG. 9, components 91 from component 90 numbered 1 to component 90 numbered 5 are collected in a right direction in the drawing. Thereafter, components 91 from component 91 numbered 6 to component 91 numbered 10 are collected in a left direction in the drawing. Then, components 91 from component 91 numbered 11 to component 91 numbered 15 are collected in the right direction in the drawing.

In tray 12b illustrated in FIG. 10, components 91 from component 90 numbered 1 to component 90 numbered 3 are collected in a down direction in the drawing. Thereafter, components 91 from component 91 numbered 4 to component 91 numbered 6 are collected in an up direction in the drawing. Then, components 91 from component 91 numbered 7 to component 91 numbered 9 are collected in the down direction in the drawing. Thereafter, components 91 from component 91 numbered 10 to component 91 numbered 12 are collected in the up direction in the drawing. Then, components 91 from component 91 numbered 13 to component 91 numbered 15 are collected in the down direction in the drawing.

In any case, as the component identification information, information indicating a collection order in a case where component 91 is collected from tray 12b by holding member 30 can be used. For example, it is assumed that acquisition section 41 acquires the component identification information for component 90 numbered 1 illustrated in FIG. 9. It is assumed that the component identification information of component 91 is represented by information BBB0001, Information BBB0001 includes symbol portion BBB and numeric portion 0001.

Numeric portion 0001 indicates a collection order in a case where component 90 numbered 1 is collected. For example, complementing section 43 can represent the component identification information of component 90 numbered 2 collected subsequent to component 90 numbered 1 by information BBB00011. Information BBB00011 includes symbol portion BBB, numeric portion 0001, and relative order portion 1. Relative order portion 1 indicates a relative order (in this case, first) for component 91 for which the component identification information is acquired by acquisition section 41 (in this case, component 91 of which the component identification information is represented by information BBB0001).

Complementing section 43 represents the component identification information of component 90 numbered 3 collected subsequent to component 90 numbered 2 by information BBB00012. In this case, the component identification information includes relative order portion 2, and relative order portion 2 indicates the relative order (in this case, second) with respect to component 91 for which the component identification information is acquired by acquisition section 41 (component 91 of which the component identification information is represented by information BBB0001). The same applies to components 91 numbered 4 and above, and the relative order indicates a collection order of components 91 starting from component 91 for which the component identification information is acquired by acquisition section 41 in a case where component supply device 12 is tray 12b. Symbol portion BBB indicates various types of information related to component 91.

As the component identification information, information indicating the position of component 91 in tray 12b can also be used. For example, the position of component 91 in tray 12b can be represented by a matrix. For example, it is assumed that acquisition section 41 acquires the component identification information for component 90 numbered 1 illustrated in FIG. 9. It is assumed that the component identification information of component 91 is represented by information CCC0101. Information CCC0101 includes symbol portion CCC and matrix portion 0101. Matrix portion 0101 indicates the position of component 90 numbered 1 in tray 12b (in this case, row 1 and column 1).

For example, complementing section 43 can represent the component identification information of component 91 numbered 15 illustrated in FIG. 9 by information CCC01010305. Information CCC01010305 includes symbol portion CCC, matrix portion 0101, and relative position portion 0305. Relative position portion 0305 indicates a relative position (in this case, row 3, column 5) with respect to component 91 for which the component identification information is acquired by acquisition section 41 (in this case, component 91 of which the component identification information is represented by information CCC0101). The same applies to other components 91, and the relative position indicates the position of component 91 in tray 12b with component 91 for which the component identification information is acquired by acquisition section 41 as the reference position, in a case where component supply device 12 is tray 12b. Symbol portion CCC indicates various types of information related to component 91.

In this way, storage section 42 can store the component identification information of component 91 acquired by acquisition section 41 or the component identification information of component 91 complemented by complementing section 43 and the board identification information for identifying board 90 on which component 91 is mounted in storage device 60 in association with each other. Storage section 42 can also store the component identification information of component 91 acquired by acquisition section 41 or the component identification information of component 91 complemented by complementing section 43, the board identification information for identifying board 90 on which component 91 is mounted, and the mounting position information for specifying the mounting position at which component 91 is mounted in board 90 in storage device 60 in association with each other.

Further, when component 91 supplied from component supply device 12 is discarded without being mounted on board 90, storage section 42 can store the component identification information of component 91 acquired by acquisition section 41 or the component identification information of component 91 complemented by complementing section 43 and discard information indicating that component 91 is discarded in storage device 60 in association with each other.

### 2. Component Management Method

The above description of component management device 40 can be similarly applied to a component management method. Specifically, the component management method includes an acquisition step and a storage step. The acquisition step corresponds to control performed by acquisition section 41. The storage step corresponds to control performed by storage section 42. The component management method may further include a complementing step. The complementing step corresponds to control performed by complementing section 43.

Further, the acquisition step may include at least one of a first acquisition step, a second acquisition step, a third acquisition step, and a fourth acquisition step. The first acquisition step corresponds to control performed by first acquisition section 41a. The second acquisition step corresponds to control performed by second acquisition section 41b. The third acquisition step corresponds to control performed by third acquisition section 41c. The fourth acquisition step corresponds to control performed by fourth acquisition section 41d.

### 3. Example of Effects of Embodiment

With component management device 40, it is possible to acquire the component identification information for predetermined component 91 supplied from component supply device 12 and store the component identification information in storage device 60. The above description of component management device 40 can be similarly applied to the component management method.

### REFERENCE SIGNS LIST

10: component mounter, 12: component supply device, 12a: feeder, 12b: tray, 20: mounting head, 30: holding member,
40: component management device, 41: acquisition section, 41a; first acquisition section,
41b; second acquisition section, 41c: third acquisition section, 41d: fourth acquisition section,
42: storage section, 43; complementing section, 60: storage device, 70: identification member,
80: carrier tape, 90: board, 91: component, 91a: first component,
91b: second component, 91c: third component, PP1: collection position.

1. A component management device comprising:
an acquisition section configured to acquire, from an identification member having component identification information for identifying components to be mounted on a board, the component identification information for at least one of a first component that is some of the multiple components that are supplied from a component supply device configured to supply the components after the component supply device is mounted on a component mounter, a second component that is some of the multiple components that are supplied from the same component supply device to the boards of the same type, and a third component that is the component selected each time a predetermined number of the components are supplied from the same component supply device and that is some of the predetermined number of the components; and
a storage section configured to store, in a storage device, the component identification information of the components that is acquired by the acquisition section and board identification information for identifying the board on which the components are mounted, in association with each other.

2. The component management device according to claim 1, wherein the acquisition section is at least one of a first acquisition section configured to acquire the component identification information from above the identification member in a case where the component is collected from the component supply device, a second acquisition section configured to acquire the component identification information from below the identification member provided on a lower surface of the component in a case where the component is held by a holding member configured to collect and hold the component to mount the component on the board, a third acquisition section configured to acquire the component identification information from above the identification member provided on an upper surface of the component in a case where the component is mounted on the board by the holding member, and a fourth acquisition section configured to acquire the component identification information via wireless communication with a wireless tag in a case where the identification member is the wireless tag.

3. The component management device according to claim 2, wherein the identification member in a case where the component identification information is acquired in the first acquisition section, the second acquisition section, or the third acquisition section is a one-dimensional code or a two-dimensional code.

4. The component management device according to claim 1, wherein the first component is the component initially supplied from the component supply device after the component supply device is mounted on the component mounter, the second component is the component initially supplied from the same component supply device to each of the boards of the same type, and the third component is the component that is first in order among the predetermined number of components.

5. The component management device according to claim 1,
wherein the component mounter includes a mounting head including a holding member configured to collect and hold the component to mount the component on the board, and
the predetermined number is the number of the holding members provided in the mounting head.

6. The component management device according to claim 1, wherein the acquisition section is configured to attempt, in a case where the component identification information is not acquired, to acquire the component identification information for at least one of the component supplied subsequent to the first component, the component supplied subsequent to the second component, and the component other than the third component among the predetermined number of components, and repeat the attempt until the component identification information is acquired.

7. The component management device according to claim 1,
wherein the component supply device is a feeder configured to pitch-feed a carrier tape in which the components are accommodated and supply the components in a collection position so that the components can be collected, and
the component identification information is information indicating an accommodation order in which the components are accommodated in the carrier tape.

8. The component management device according to claim 1,
wherein the component supply device is a tray on which the components are arranged, and
the component identification information is information indicating a collection order in a case where the components are collected from the tray by a holding member configured to collect and hold the components to mount the components on the board, or information indicating positions of the components on the tray.

9. The component management device according to claim 1, further comprising:
a complementing section configured to complement the component identification information of the component for which the component identification information is not acquired by the acquisition section, based on a relative order or a relative position with respect to the component for which the component identification information is acquired by the acquisition section.

10. The component management device according to claim 9, wherein the storage section is configured to store, in the storage device, the component identification information of the component that is acquired by the acquisition section or the component identification information of the component that is complemented by the complementing section, the board identification information for identifying the board on which the component is mounted, and mounting position information for specifying a mounting position at which the component is mounted on the board, in association with each other.

11. A component management method comprising:
an acquisition step of acquiring, from an identification member having component identification information for identifying components to be mounted on a board, the component identification information for at least one of a first component that is some of the multiple components that are supplied from a component supply device configured to supply the components after the component supply device is mounted on a component mounter, a second component that is some of the multiple components that are supplied from the same component supply device to the boards of the same type, and a third component that is the component selected each time a predetermined number of the components are supplied from the same component supply device and that is some of the predetermined number of the components; and
a storage step of storing, in a storage device, the component identification information of the components that is acquired by the acquisition step and board identification information for identifying the board on which the components are mounted, in association with each other.
